(19) United States
(12) Patent Application Publication
(10) Pub. No.: US 2013/0140584 A1
(43) Pub. Date: Jun. 6, 2013

(54) SEMICONDUCTOR DEVICE

(71) Applicants: Norifumi Kameshiro, Tokyo (JP); Natsuki Yokoyama, Mitaka (JP)

(72) Inventors: Norifumi Kameshiro, Tokyo (JP); Natsuki Yokoyama, Mitaka (JP)

(21) Appl. No.: 13/700,729

(22) PCT Filed: Jun. 2, 2010
(86) PCT No.: PCT/JP2010/059362

§ 371 Date: Feb. 19, 2013

(51) Int. Cl. H01L 29/16

(52) U.S. Cl. CPC H01L 29/1608
USPC 257/77

(57) ABSTRACT

Disclosed is a JBS diode wherein an increase in an on-voltage is suppressed by sufficiently spreading a current to the lower portion of a junction barrier (p⁺) region. The JBS diode has a structure, which has an n region having a relatively high concentration compared with the n− drift layer concentration, said n region being in the lower portion of the junction barrier (p⁺) region.

### TECHNICAL FIELD

The present invention relates to a semiconductor device and in particular to a technology that is effective when applied to a junction barrier Schottky diode which uses silicon carbide.

### BACKGROUND ART

Features of a silicon carbide semiconductor (SiC) are that it has a wider band gap than a silicon semiconductor and that it has a breakdown field one digit higher than a silicon semiconductor. For these reasons, silicon carbide semiconductors are believed to be promising as a power device. In particular, a Schottky diode for a unipolar rectifier that is driven by only majority carriers does not conduct reverse current (recovery current) during a switching operation owing to the device configuration. Accordingly, such a Schottky diode is effective as a technology for reducing a loss in a power module.

The rectification effect of a Schottky diode is achieved by a Schottky barrier that occurs due to the difference between the work function of a metal and the electron affinity of a semiconductor. Use of a metallic material having a high Schottky barrier can reduce the reverse leakage current but increases the forward threshold voltage. Use of a metallic material having a low Schottky barrier can reduce the forward threshold voltage but increases the reverse leakage current.

A structure where multiple Schottky barriers are disposed over a Schottky interface, called a junction barrier Schottky diode (hereafter referred to as “JBS diode”), is proposed as a structure for suppressing the reverse leakage current by reducing an electric field applied to a metal/semiconductor interface (hereafter referred to as “Schottky interface”) during application of a reverse voltage. During application of a reverse voltage, a depletion layer extends from the junction barrier, allowing a field over the Schottky interface to be reduced. This structure is illustrated in FIG. 19. In FIG. 19, 1 represents a silicon carbide n⁺ substrate; 2 an n⁻ drift layer; 3 a p⁺ region; 5 an anode electrode; and 6 a cathode electrode. While a JBS diode can reduce the reverse leakage current, the resistance thereof is increased during a forward operation. This is because the area of the Schottky diode region that is driven by a low voltage is reduced during the forward operation. A structure where the region surrounded by the junction barrier has an increased impurity concentration is proposed as a structure for controlling increases in the resistance of a JBS diode during a forward operation (Patent Literature 1). This structure is illustrated in FIG. 20. FIG. 20 differs from FIG. 19 in that an n-type semiconductor region 4 having a higher impurity concentration than the n⁻ drift layer is disposed. This structure can reduce the resistance of the junction barrier formation region.

### CITATION LIST

### Patent Literature

Patent Literature 1: Japanese Patent No. 3987957

### SUMMARY OF INVENTION

### Technical Problem

However, these considerations are an effective method only when an ideal Schottky interface can be formed. Reverse characteristics of a Schottky diode are very sensitive to the state of the Schottky interface. Presence of a foreign particle or defect around the interface sharply increases the reverse leakage current, failing to obtain the desired rectification effect. Generally, a Schottky diode has a lower yield rate than a PN diode. The reason is that compared to a PC diode, which is obtained by forming a junction barrier in a drift layer by epitaxial growth or ion implantation, a Schottky diode, which is obtained by forming a metallic film over a surface of a drift layer, is subject to the effect of a foreign particle, or a process defect during a manufacturing process. Assuming that foreign particles or defects are randomly distributed, a yield rate Y (which represents a probability that chips can be manufactured without causing abnormality to reverse characteristics) can be considered in view of the Poisson distribution and represented by the following formula.

Y=exp(−DA) (Formula)

D: the density of foreign particles or defects that cause abnormality to reverse characteristics
A: the area of the Schottky interface

FIG. 21 shows a graph where the relationship between the yield rate Y represented by Formula I and the area A of the Schottky interface is plotted with respect to a defect density D. The graph shows that, for example, when the area A of the Schottky interface is 0.1 cm², a yield rate Y of about 90% corresponds to D of one piece/cm²; Y of 40% or less, that is, significantly reduced Y corresponds to D of ten pieces/cm². A value obtained by multiplying this value by a yield rate corresponding to the total area of a junction barrier region used in the JBS structure, or the field concentration relaxing structure formed around the chip can be considered as the yield rate of the JBS diode.

As described above, a Schottky diode is sensitive to characteristics of the Schottky interface and therefore it is very difficult to manufacture a withstand-voltage, non-defective chip having a large area. Accordingly, enlargement of the junction barrier region and minimization of the Schottky interface region in the JBS structure are considered to be effective in improving the yield rate. In this case, however, a problem occurs that the current does not sufficiently spread to the bottom of the junction barrier region during a forward operation and thus the on-voltage increases.

That is, the problem to be solved is that since the current does not sufficiently spread to the bottom of the junction barrier region during a forward operation of the JBS diode, the on-voltage increases.

### Solution to Problem

The present invention is a structure where an n region having a higher concentration than an n⁻ drift layer is disposed below a junction barrier region so as to control increases in the on-resistance of a JBS structure diode. Typical examples of the present invention are described below.

An aspect of the present invention provides a semiconductor device. The semiconductor device includes: a silicon carbide substrate of a first conductivity-type; a drift layer of the first conductivity-type formed over the silicon carbide substrate and having a first impurity concentration; a plurality of first semiconductor regions of a second conductivity-type formed over a surface in the drift layer at predetermined intervals, the second conductivity-type being opposite to the first conductivity-type; a Schottky electrode which is Schottky connected to the drift layer; an ohmic electrode which is ohmic connected to a back surface of the silicon carbide substrate; and a second semiconductor region of the first conductivity-type disposed in a region between the first semiconductor regions and the silicon carbide substrate, the second semiconductor region having a second impurity concentration higher than the first impurity concentration.

Another aspect of the present invention provides a semiconductor device. The semiconductor device includes: a silicon carbide substrate of a first conductivity-type; a first semiconductor layer of the first conductivity-type formed over the silicon carbide substrate and having a first impurity concentration; a second semiconductor layer of the first conductivity-type formed over the first semiconductor layer and having a second impurity concentration higher than the first impurity concentration; a plurality of first semiconductor regions of a second conductivity-type formed over a surface in the second semiconductor layer at predetermined intervals, the second conductivity-type being opposite to the first conductivity-type; a Schottky electrode which is Schottky connected to the second semiconductor layer; and an ohmic electrode which is ohmic connected to a back surface of the silicon carbide substrate.

Yet another aspect of the present invention provides a semiconductor device. The semiconductor device includes: a silicon carbide substrate of a first conductivity-type; a first semiconductor layer of the first conductivity-type formed over the silicon carbide substrate and having a first impurity concentration; second semiconductor layer of the first conductivity-type formed over the first semiconductor layer and having a second impurity concentration higher than the first impurity concentration; a plurality of first semiconductor regions of a second conductivity-type formed over a surface in the second semiconductor layer at predetermined intervals, the second conductivity-type being opposite to the first conductivity-type; second semiconductor region of the second conductivity-type formed in the second semiconductor layer so as to surround the first semiconductor regions when seen from above; a Schottky electrode which is Schottky connected to the second semiconductor layer; and an ohmic electrode which is ohmic connected to a back surface of the silicon carbide substrate.

### Advantageous Effects of Invention

The semiconductor devices according to the aspects of the present invention have the n region having a lower resistance than the n⁻ drift layer below the junction barrier region. Thus, the current spreads to the bottom of the junction barrier region, allowing increases in the on-voltage of the JBS diode to be controlled.

### BRIEF DESCRIPTION OF DRAWINGS

FIG. 1 is a diagram showing a sectional structure of a semiconductor device according to a first embodiment of the present invention and is a sectional view obtained by cutting FIG. 22 along A-A′.

FIG. 2 is a diagram showing a sectional structure in an example manufacturing process step of the semiconductor device according to the first embodiment of the present invention.

FIG. 3 is a diagram showing a sectional structure in a semiconductor device manufacturing process step following FIG. 2.

FIG. 4 is a graph showing the relationship between the resistance increase rate of a drift layer and the percentage of a Schottky interface.

FIG. 5 is a graph showing the relationship between the resistance increase rate of the drift layer and the width of a junction barrier region.

FIG. 6 is a graph showing effects according to the first embodiment of the present invention.

FIG. 7 is a graph showing effects, according to the first embodiment of the present invention.

FIG. 8 includes diagrams showing a sectional structure of a semiconductor device according to a second embodiment of the present invention and specifically includes sectional views obtained by cutting FIG. 22 along B-B′, in which (a) is a sectional view where a Schottky electrode is not disposed over an insulating film 10 and (b) is a sectional view where a Schottky electrode is disposed over the insulating film 10.

FIG. 9 is a diagram showing a sectional structure of a semiconductor device according to a third embodiment of the present invention.

FIG. 10 is a diagram showing a sectional structure of another semiconductor device according to the third embodiment of the present invention.

FIG. 11 is a diagram showing a sectional structure in an example manufacturing process step of the semiconductor device according to the third embodiment of the present invention.

FIG. 12 is a diagram showing a sectional structure in a semiconductor device manufacturing process step following FIG. 11.

FIG. 13 is a diagram showing a sectional structure of a semiconductor device according to a fourth embodiment of the present invention.

FIG. 14 is a diagram showing a sectional structure in an example manufacturing process step of the semiconductor device according to the fourth embodiment of the present invention.

FIG. 15 is a diagram showing a sectional structure in a semiconductor device manufacturing process step following FIG. 14.

FIG. 16 is a diagram showing a sectional structure of a semiconductor device according to a fifth embodiment of the present invention.

FIG. 17 is a diagram showing a sectional structure in an example manufacturing process step of the semiconductor device according to the fifth embodiment of the present invention.

FIG. 18 is a diagram showing a sectional structure in a semiconductor device manufacturing process step following FIG. 16.

FIG. 19 is a diagram showing a sectional structure of a traditional semiconductor device.

FIG. 20 is a diagram showing a sectional structure of a traditional semiconductor device.

FIG. 21 is a graph showing the relationship between a yield rate and the area of a Schottky interface.

FIG. 22 is a diagram showing the top structure of the semiconductor device according to the first embodiment of the present invention.

### DESCRIPTION OF EMBODIMENTS

Hereafter, embodiments of the present invention will be described in detail based on the drawings. The same components are basically given the same reference signs throughout the drawings for showing the embodiments and will not be described repeatedly. In particular, components according to different embodiments whose functions correspond to each other are given the same reference signs, even if the components differ from each other in shape, impurity concentration, crystallinity, or the like. Sectional views show only main portions of diodes, and peripheral portions thereof, including an electric field concentration relaxing structure, which is typically formed around a chip, are omitted. While only an example where an n-type semiconductor substrate is used will be described for the sake of convenience, the present invention also includes examples where a p-type semiconductor substrate is used. In this case, n-type may be read as being p-type, and vice versa.

### First Embodiment

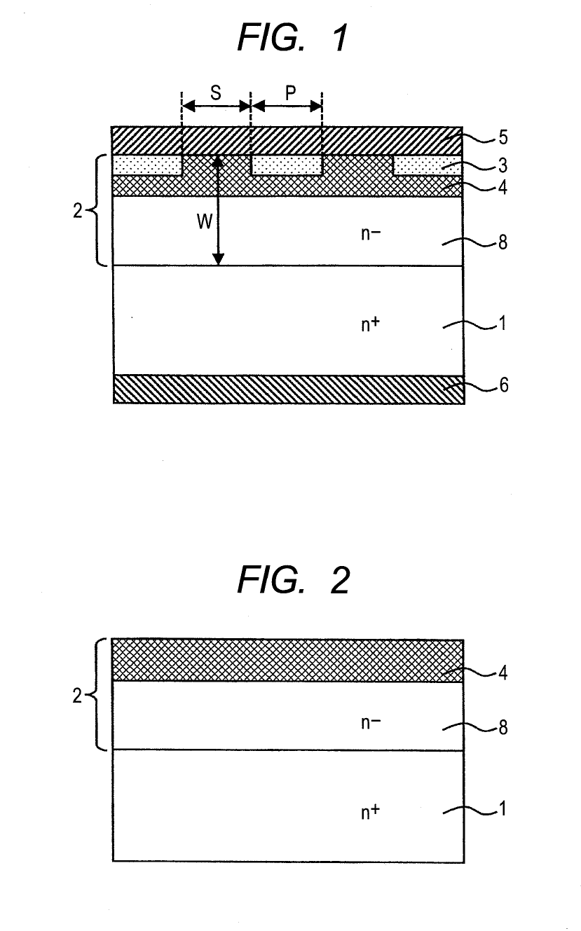

FIG. 1 is a diagram showing a sectional structure of a semiconductor device according to a first embodiment of the present invention. The semiconductor device according to the first embodiment is a JBS diode that includes a SiC drift layer 2 of a first conductivity-type (n-type) having a low impurity concentration (n⁻) and formed over a SiC substrate 1 of the first conductivity-type having a high impurity concentration (n⁺); multiple p-type semiconductor regions 3 of a second conductivity-type (p-type); a Schottky electrode 5 disposed over a surface of the n⁻ drift layer 2; and an ohmic electrode 6 disposed over the back surface of the n⁺ SiC substrate 1. This diode also has an n-type semiconductor region 4 having a higher impurity concentration than the n⁻ drift layer 2 (n⁻ SiC semiconductor layer 8) in a region below the p-type semiconductor regions 3 and between the p-type semiconductor regions 3 and the SiC substrate. Thus, the current can sufficiently spread to the bottoms of the p-type semiconductor regions 3 during a forward operation, controlling increases in on-voltage. In the first embodiment, the n-type semiconductor region 4 is disposed below the p-type semiconductor regions 3 so as to be in contact with the p-type semiconductor regions 3. Since the n-type semiconductor region 4 is formed over the entire surface of the n⁻ drift layer 2, it is also present in regions between the p-type semiconductor regions 3. W represents the thickness of the drift layer; S the interval between the p-type semiconductor regions 3; and P the width of each p-type semiconductor region 3.

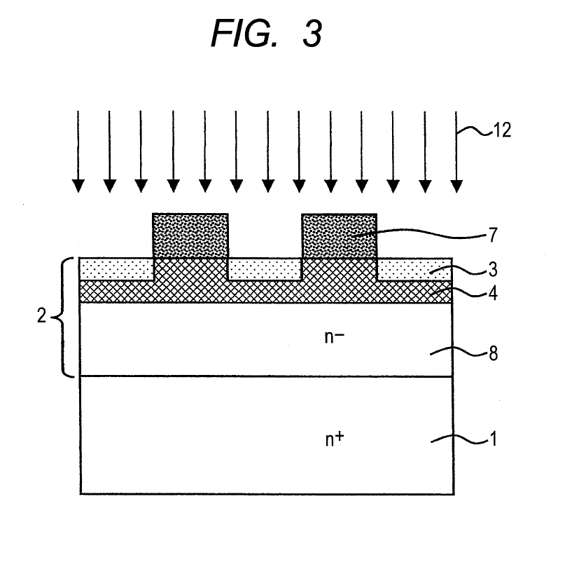

FIGS. 2 and 3 are diagrams each showing a sectional structure in an example manufacturing process step according to the first embodiment.

As shown in FIG. 2, a SiC substrate is prepared where the n⁻ SiC semiconductor layer 8 is epitaxially grown over the n⁺ SiC substrate 1; and the n-type semiconductor region 4 having a higher impurity concentration than the n⁻ SiC semiconductor layer 8 is epitaxially grown over the n⁻ SiC semiconductor layer 8. The multilayer film composed of the n⁻ SiC semiconductor layer 8 and the n-type semiconductor region 4 is defined as the n⁻ drift layer 2.

A range of the order of 1×10¹⁸ to 1×10¹⁸ cm⁻³ is used as the range of the impurity concentration of the n⁺ SiC substrate 1. A (0001) surface, (000-1) surface, or (11-20) surface is often used as the main surface of the SiC substrate. The present invention can show its effects regardless of which of these surfaces is selected as the main surface of the SiC substrate.

For specifications of the n− SiC semiconductor layer 8 over the n⁺ SiC substrate 1, the conductivity type is the same as the substrate; the impurity concentration is in a range of the order of 1×10¹⁵ to 4×10¹⁸ cm⁻³; and the thickness is in a range of the order of 3 to 80 μm. Note that the specifications depend on the prescribed withstand voltage specification.

Subsequently, as shown in FIG. 3, a mask material 7 is patterned by normal lithography and dry etching. In this embodiment, Si0₂ formed by chemical vapor deposition (CVD) is used as the mask material 7. The mask material 7 is typically shaped into a stripe pattern, insular pattern, polygonal pattern, grid pattern, or the like. In the present invention, the mask material 7 of any shape can show its effects, as long as it is patterned with constant widths and intervals. After patterning the mask material 7, the p-type semiconductor regions 3 are formed over a surface of the n⁻ drift layer 2 by implanting ions 12. A range of the order of 10¹⁸ to 10²⁰ cm⁻³ is used as the range of the impurity concentration of the p-type semiconductor regions 3; a range of the order of 0.3 to 2.0 μm as the range of a junction depth thereof. Generally, aluminum (Al) or boron (B) is used as a p-type dopant. In this embodiment, a total dose of 1.8×10¹⁴ cm⁻² of Al is implanted as a dopant with acceleration energy of 35 to 145 keV in multiple stages. Thus, the p-type semiconductor regions 3 are formed with an impurity concentration on the order of 9×10¹⁸ cm⁻³ around surfaces thereof and a junction depth on the order of 0.55 to 0.7 μm.

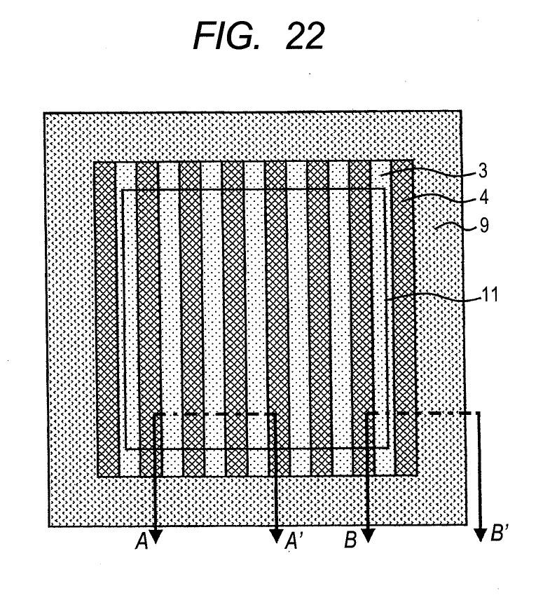

After forming the p-type semiconductor regions 3 in this way, a guard ring 9 is formed of a p-type impurity over the outer periphery of the chip in the same steps that the p-type semiconductor regions 3 are formed (see FIG. 22). Subsequently, the implanted impurity is subjected to activation annealing, which is usually performed; the ohmic electrode 6 is formed over the back surface of the n⁺ SiC substrate; the Schottky electrode 5 is formed over the surface of the n⁻ drift layer 2; and the Schottky electrode 5 is patterned into the desired size. Thus, the main portions of the semiconductor device according to the present invention shown in FIG. 1 are completed.

Note that, to protect a surface and prevent discharge from a terminal of the electrode, an insulating film 10 is formed of SiO₂ over the surface, and some regions at the top of the electrode are patterned into an aperture 11 for the electrode terminal. Thus, the semiconductor device is completed (see FIG. 22). FIG. 22 is a diagram showing the top structure of the first embodiment. Note that this top view shows the positional relationship among the main portions of the semiconductor device and does not correctly show the positions or sizes of all the layers. Further, to make the positional relationship easy to understand, some layers such as the electrode are not shown. While this JBS structure shows a stripe pattern where the p-type semiconductor regions 3 are arranged in the form of lines at constant intervals, an insular pattern, polygonal pattern, grid pattern, or the like, which is commonly used in a JIBS structure, may be used, as described above. The p-type semiconductor region 9 is formed so as to surround the multiple p-type semiconductor regions 3. FIG. 1 is a sectional view obtained by cutting FIG. 22 along A-A′. While only the main portions of the diode have been described thus far, an electric field concentration relaxing structure such as a field limiting ring (FLR) or junction termination extension (JTE) or a channel stopper, which is usually formed over the periphery of the chip, is formed by normal lithography and dry etching, and ion implantation before or after forming the p-type semiconductor regions 3 shown in FIG. 3.

While the SiC substrate having the n-type semiconductor region 4 epitaxially grown thereover is used in the first embodiment, the n-type semiconductor region 4 may be formed by ion-implanting an n-type impurity into the n⁻ drift layer 2 in multiple stages. While nitrogen (N) or phosphorus (P) is typically used as an n-type impurity, any other elements which serve as an n-type dopant may be used. In this case, the region into which the n-type impurity is to be implanted may be the entire surface of the SiC substrate or may be limited to the region in which the Schottky electrode is to be formed. Further, the n-type impurity may be ion-implanted before the step of activation-annealing the implanted impurity, and the n-type semiconductor region 4 may be formed after the step of forming the p-type semiconductor regions 3 of FIG. 3.

While SiO₂ is used as a mask material in the first embodiment, a silicon nitride film or resist material, for example, may be used. Any other materials may be used, as long as they are materials that serve as a mask during ion implantation.

While, in the first embodiment, the electrodes are formed over the back and front surfaces immediately after activation-annealing the implanted impurity, an oxidation process and a sacrificial oxidation step of eliminating a damaged layer which has entered a surface of the n⁻ drift layer 2 may be performed after activation-annealing the implanted impurity.

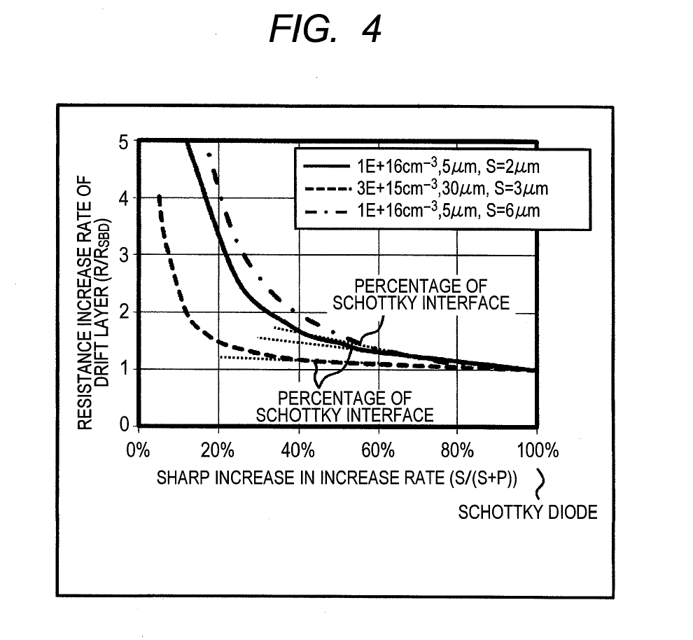

While, in the first embodiment, the electrodes are formed over the back and front surfaces immediately after activation-annealing the implanted impurity, a surface protection film may be formed of SiO₂ or the like over the surface of the n⁻ drift layer 2 by CVD to protect the surface of the n⁻ drift layer 2. In this case, an aperture is formed only in the region in which a Schottky electrode is to be formed, of the formed surface protection film. Alternatively, surface protection film may be formed after performing the sacrificial oxidation step. Next, an example of effects of the present invention will be described using simulation results of FIGS. 4 to 7. The resistance of n⁻ drift layer of the diode having a JBS structure is defined as R; the resistance of the n⁻ drift layer of the Schottky diode as R_{SBD}; the width of the p-type semiconductor region 3 in the JBS structure as P; and the thickness of the n⁻ drift, layer 2 as W.

For the n⁻ drift layer 2, two different withstand voltage specifications are shown. One n-drift layer has an estimated withstand voltage of 600 V, an impurity concentration of 1×10¹⁶ cm⁻³, and a thickness of 5 μm; the other n-drift layer has an estimated withstand voltage of 3.3 kV, an impurity concentration of 3×10¹⁵ cm⁻³, and a thickness of 30 μm.

FIG. 4 shows the relationship between the rate of resistance increase of a traditional JBS diode, R/R_{SBD}, and the percentage of the Schottky interface, S/(S+P). The spacing S between p⁺ junction regions is determined in consideration of sufficiently reducing an electric field over the Schottky electrode interface during application of a reverse voltage and thus reducing the reverse leakage current. An S of 2 μm is set as a standard specification of the n⁻ drift layer 2 having an estimated withstand voltage of 600V; an S of 3 μm is set as a standard specification of the n⁻ drift layer 2 having an estimated withstand voltage of 3.3 kV. To compare changes in resistance among drift layers, a calculation is also made with respect to an S specification of 6 μm of an n-drift layer 2 having a withstand voltage of 600 V. However, this S specification is not a value in which consideration is given to the effect of reducing en electric field over the Schottky interface. FIG. 4 shows that the use of the JBS structure restricts the current path over the surface of the n⁻ drift layer 2 and thus the rate of resistance increase R/R_{SBD} increases as the percentage of the Schottky interface decreases. However, the sensitivity of the resistance increase rate of the drift layer to the percentage of the Schottky interface varies according to the specifications of the n⁻ drift layer 2 or the size of the spacing S. That is, FIG. 4 shows that the current does not sufficiently spread to the bottom of the p-type semiconductor region and that the point at which the resistance increase rate R/R_{SBD} sharply increases is not determined by only the ratio between the width P and the spacing S between the p-type semiconductor regions.

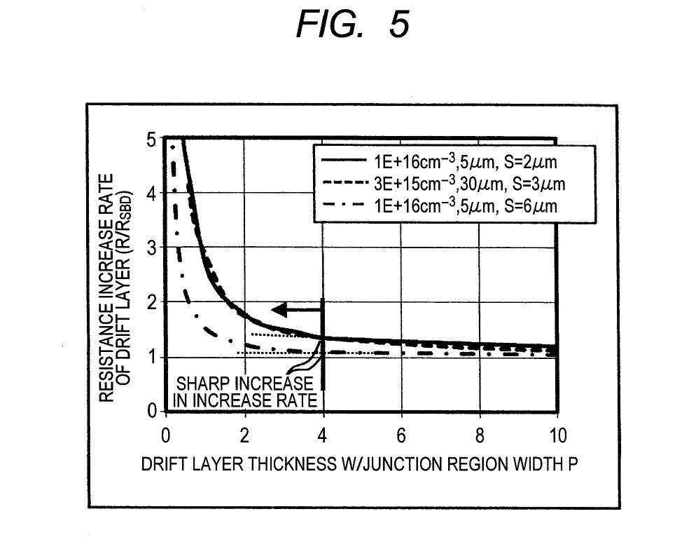

FIG. 5 shows the relationship between the resistance increase rate R/R_{SBD} of a traditional JBS diode and the ratio of the width of the junction region to the thickness of the drift layer, W/P. FIG. 5 shows that while the rate of resistance increase R/R_{SBD} increases at a moderate, approximately constant rate when W/P has large values, it sharply increases in the region of W/P≦4. This means that the factor that determines increases in the resistance of the JBS structure is determined by the width of the p-type semiconductor region, P, and the thickness of the drift layer, W, and that the current does not sufficiently spread to the bottom of the p-type semiconductor region 3 in a relationship of P≧W/4.

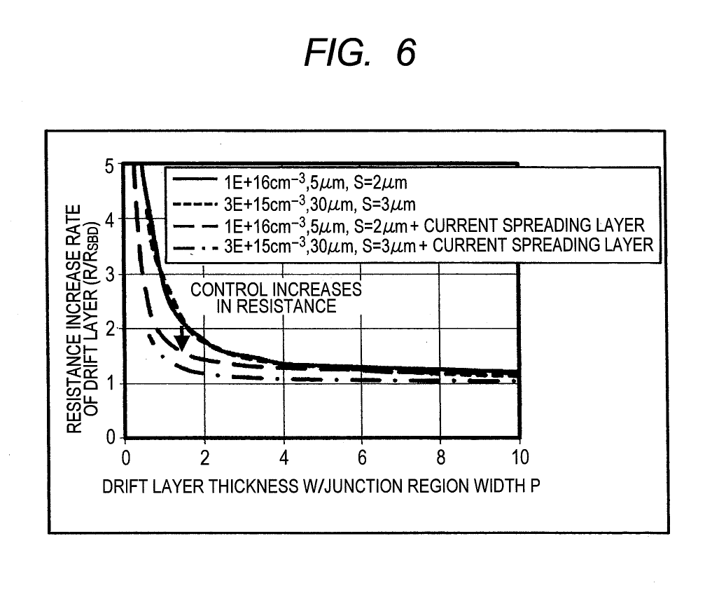

FIG. 6 shows an example of effects when the structure according to the first embodiment is applied. In FIG. 6, although the n-type semiconductor region 4 is represented as a current spreading layer for the sake of convenience, both represent the same layer. That is, lines whose description includes an expression of “current spreading layer” represent data in the case where the n-type semiconductor region 4 according to the present invention is disposed; lines whose description includes no expression of “current spreading layer” are traditional SBDs. The n⁻ drift layer 2 having an estimated withstand voltage of 600 V is a multilayer film composed of the n⁻ SiC semiconductor layer 8 having an impurity concentration of 1×10¹⁶ cm⁻³ and a thickness of 5 μm as specifications and the n-type semiconductor region 4 having an impurity concentration of 3×10¹⁶ cm⁻³ and a thickness of 2 μm as specifications. The n⁻ drift layer 2 having an estimated withstand voltage of 3.3 kv is a multilayer film composed of the n− SiC layer 8 having an impurity concentration of 3×10¹⁵ cm⁻³ and a thickness of 30 μm as specifications and the n-type semiconductor region 4 having an impurity concentration of 1.5×10¹⁶ cm⁻³ and a thickness of 2 μm as specifications. The rate of resistance increase of the n⁻ drift layer 2 including the n-type semiconductor region 4 is standardized based on the resistance R_{SBD} of the Schottky diode of the n⁻ drift layer 2 including no n-type semiconductor region 4. For this reason, the rate of resistance increase R/R_{SBD} when W/P has large values varies according to the impurity concentration and thickness of the multilayer film, that is, the specifications of the n⁻ drift layer 2. However, it is understood that, compared to the n-drift layers 2 having the traditional structure, both the n⁻ drift layers 2 having the different specifications control increases in resistance when W/P is smaller than 4, which is the point at which the rate of resistance increase sharply increases. That is, it is understood that when the n-type semiconductor region 4 according to the present invention is disposed, resistance increase control effects become remarkable, particularly in designs where P is greater than ¼ of W. While certain effects can be obtained by disposing the n-type semiconductor region 4, regardless of the relationship between P and W, more remarkable effects can be obtained by making P greater than ¼ of W. Accordingly, it is preferred to make P greater than ¼ of W.

FIG. 7 shows an example of effects when the structure according to the first embodiment is applied. Specifically, FIG. 7 shows a case when the rate of resistance increase of the n⁻ drift layer 2 including the n-type semiconductor region 4 is standardized based on the resistance R_{SBD} of a Schottky diode having the same n⁻ drift layer 2 structure. It is understood that, in each n⁻ drift layer 2 having different specifications, the rate of resistance increase R/R_{SBD} increases at a moderate, approximately constant rate until W/P becomes about 3. The reason is that owing to the structure of the present invention including the n-type semiconductor region 4, the current sufficiently spreads to the bottom of the p-type semiconductor region 3 even when the width of the p-type semiconductor region 3, P, is increased. Further, compared to the traditional structure, increases in resistance are moderate even when W/P is smaller than 3, which is the point at which the increase rate sharply increases. Even when W/P is 1, the rate of resistance increase is approximately 1.5 and is confined within a practicable range. That is, by disposing the n-type semiconductor region 4 according to the present invention, the point at which the rate of resistance increase sharply increases, which is traditionally W/P of about 4, can be reduced to W/P of about 3. Further, by disposing the n-type semiconductor region 4, a design value that is not traditionally practicable due to a high resistance increase rate when W/P is 1 can be confined within a practicable design value range. Accordingly, in order to use the region preceding a sharp increase in increase rate, it is preferred to make P larger than ¼ of W and smaller than ⅓ thereof. Further, when P is larger than ⅓ of W, which is a region following the sharp increase in increase rate, the increase rate can be kept low.

While the first embodiment has been described using the case where the n-type semiconductor region 4 has a film thickness of 2 μm, the concentration and film thickness of the n-type semiconductor region 4 can be set to any values. Specifically, the concentration of the n-type semiconductor region 4 may be set to a higher concentration than the n⁻ SiC semiconductor layer 8 and within a range where the desired withstand voltage can be shown as reverse characteristics. Similarly, the film thickness may be reduced or increased.

In the first embodiment, the spacing S between the p-type semiconductor regions 3 in the JBS structure is set to 2 μm as a specification of the n⁻ drift layer 2 having an estimated withstand voltage of 600 V; it is set to 3 μm as a specification of the n⁻ drift layer 2 having an estimated withstand voltage of 3.3 kV. However, the spacing S may be set to a smaller value, as long as the value falls within a range where the on-voltage does not extremely increase during a forward operation. In the first embodiment, the surface of the n⁻ drift layer 2 is provided with the n-type semiconductor region 4 having a relatively high impurity concentration. Accordingly, a significantly smaller spacing S than the normal spacing S can be set.

### Second Embodiment

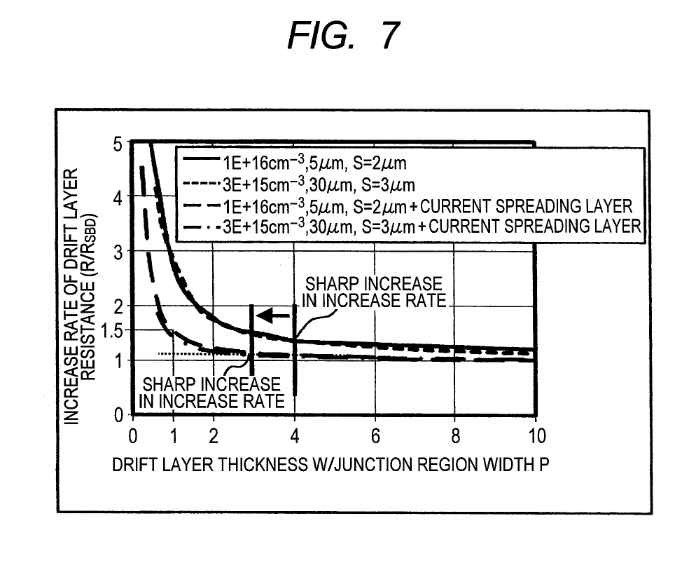

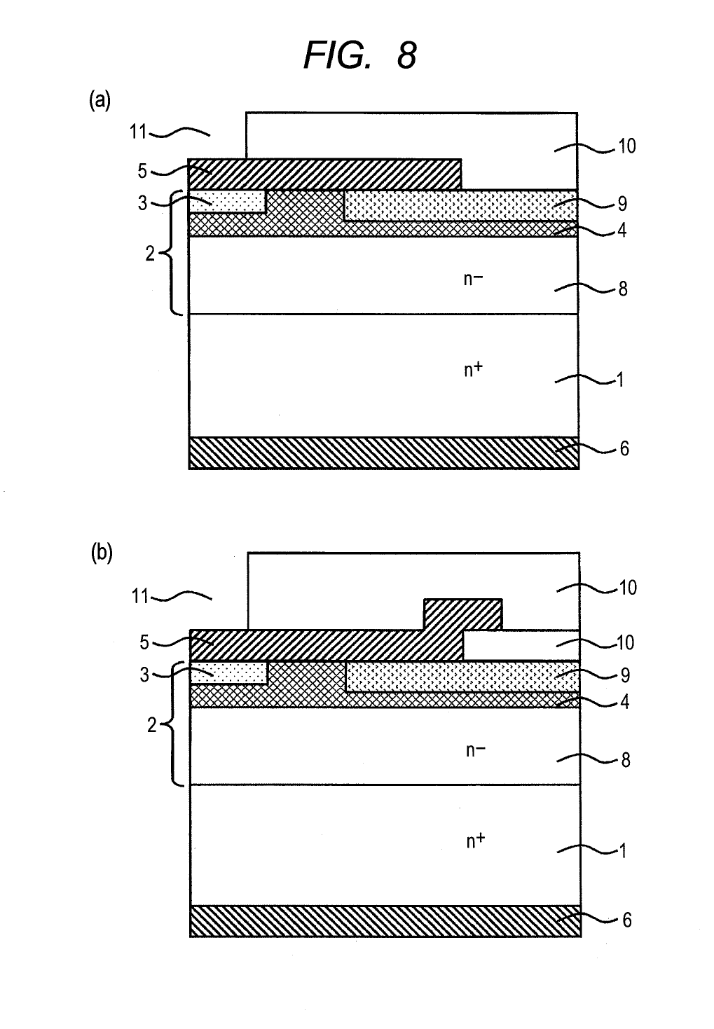

A structure according to a second embodiment is a structure obtained by additionally disposing an n-type semiconductor region 4 in a structure around a terminal of the Schottky electrode 5 according to the first embodiment. FIG. 8 is a sectional view obtained by cutting FIG. 22 along B-B′ and shows a sectional structure around the terminal of the Schottky electrode 5 of the JBS diode. As shown in FIG. 8, the following structures are typically used as the structure of the terminal of the Schottky electrode 5: (a) a structure obtained by forming the Schottky electrode 5 over the n⁻ SiC drift layer 2 in such a manner that a terminal thereof is formed over the p-type semiconductor region (guard ring) 9; and (b) a structure obtained by shaping the insulating film 10 formed over the n⁻ SiC drift layer 2 by normal lithography and dry etching or wet etching and forming the Schottky electrode 5 and shaping it in such a manner that a terminal thereof is formed over the p-type semiconductor region (guard ring) 9, as well as over the insulating film 10. The p-type semiconductor region (guard ring) 9 is disposed in such a manner that an electric field does not concentrate on the terminal of the Schottky electrode 5 or the boundary between the electrode and the insulating film 10. In any case, the terminal of the Schottky electrode or the boundary between the Schottky electrode and the insulating film 10 (the terminal of the Schottky electrode) is disposed over this p-type semiconductor region. While the p-type semiconductor region (guard ring) 9 is described as a region formed in a step different from the step in which the p-type semiconductor region 3 is formed, it may be formed in the same step as the p-type semiconductor region 3. In any case, by forming the p-type semiconductor region (guard ring) 9 in the n-type semiconductor region 4, the current can sufficiently spread to the bottom of the p-type semiconductor region (guard ring) 9 during a forward operation. Further, as in the effects of the first embodiment, increases in the on-voltage around the terminal of the Schottky electrode 5 can be controlled.

While SiO₂ is used as the insulating film 10 in the first embodiment, any materials having typical insulation properties can be used. For example, a silicon nitride film, a polyimide film, or a multilayer film composed of these different insulating films may be used.

### Third Embodiment

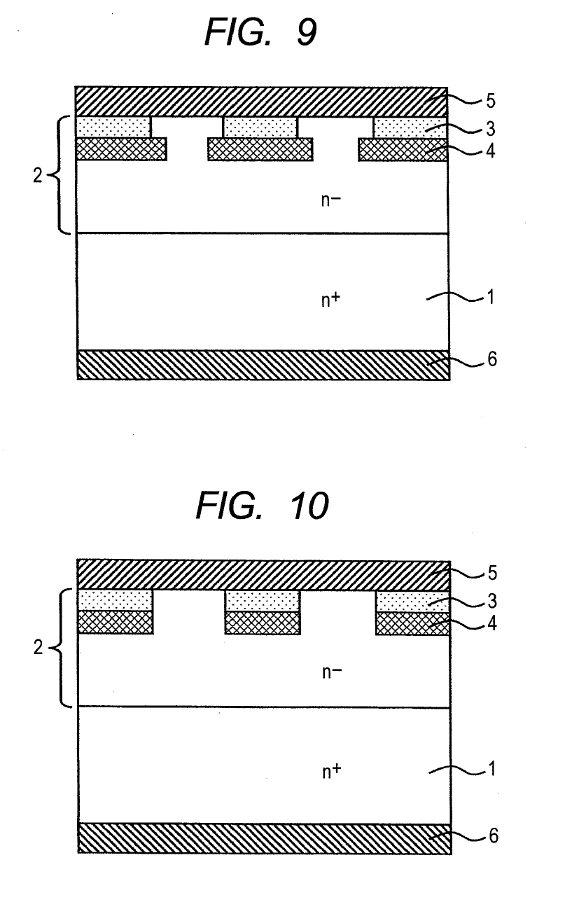

FIG. 9 is a diagram showing a sectional structure of a semiconductor device according to a third embodiment of the present invention. FIG. 10 shows a diagram showing a sectional structure of another semiconductor device according to the third embodiment. FIG. 10 differs from FIG. 9 in that the n-type semiconductor regions 4 have the same width as the p-type semiconductor regions 3. This difference can be achieved by slightly changing the manufacturing process. The third embodiment differs from the first embodiment in that the n-type semiconductor regions 4 are formed only below the p-type semiconductor regions 3. Accordingly, both embodiments differ from each other in the manufacturing process. However, effects of the third embodiment are substantially similar to those shown in the first embodiment to one degree or another.

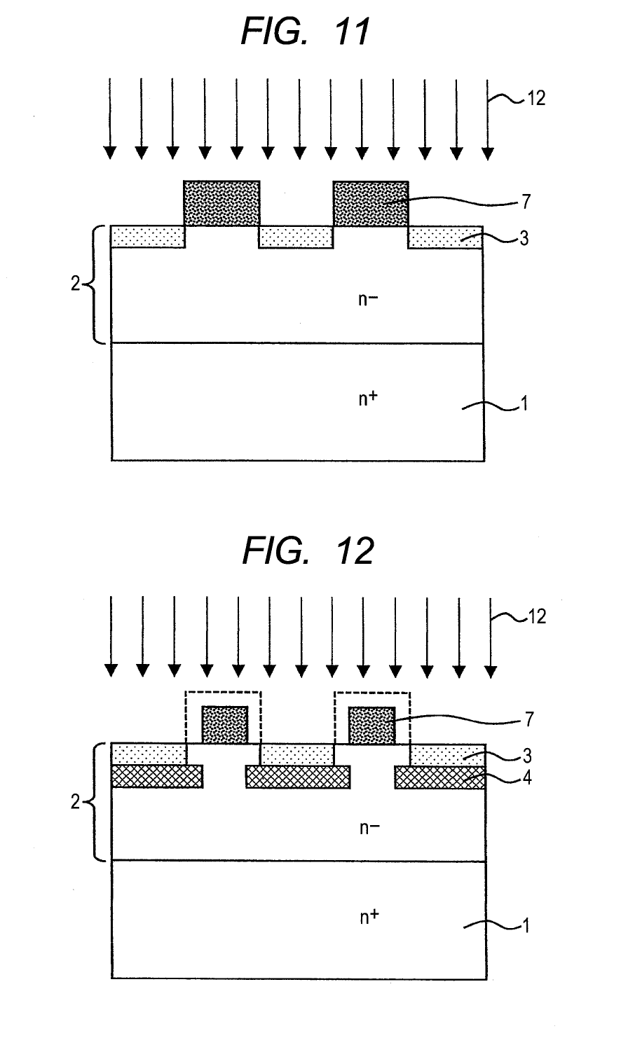

FIGS. 11 and 12 are diagrams each showing a sectional structure in an example manufacturing process step according to the third embodiment.

As in the first embodiment, a SiC substrate having the n⁻ drift layer having a low impurity concentration epitaxially grown over the n⁺ SiC substrate 1 is prepared. The impurity concentration and thickness ranges similar to those in the first embodiment are used as the specifications of the n⁺ SiC substrate 1 and the n⁻ drift layer 2.

Subsequently, as shown in FIG. 11, the mask material 7 is patterned by normal lithography and dry etching. The mask material 7 and the pattern thereof are similar to those used in the first embodiment. After patterning the mask material 7, the p-type semiconductor regions 3 are formed over a surface of the n⁻ drift layer 2 by implanting the ions 12. During ion implantation, acceleration energy and a total dose similar to those in the first embodiment are used.

Subsequently, the mask material 7 used when forming the p-type semiconductor regions 3 is contracted, and then an n-type impurity is ion-implanted to form the n-type semiconductor regions 4. Since SiO₂ formed by CVD is used as the mask material 7 in this embodiment, diluted hydrofluoric acid is used to contract the mask material 7. The amount of the mask material 7 to be etched is not limited to a particular amount and may be any amount as long as the width of the n-type semiconductor regions 4 is greater than that of the p-type semiconductor regions 3. The impurity concentration of the n-type semiconductor regions 4 is required to be higher than that of the n⁻ drift layer 2, and a setting is made such that portions around the PN junction positions below the p-type semiconductor regions 3 have a peak impurity concentration. Nitrogen (N) or phosphorus (P) is normally used as an n-type dopant. In this embodiment, using N as a dopant, a total dose of 1.8×10¹² cm⁻² is implanted with acceleration energy of 360 to 480 kev in multiple stages. Thus, the n-type semiconductor regions 4 having a peak impurity concentration of about 7×10¹⁶ cm⁻³ are formed. To increase the width of the n-type semiconductor regions 4 serving as a current spreading layer, multi-stage implantation may be performed with higher acceleration energy of, for example, up to about 700 kev. A condition for ion-implanting an n-type impurity needs to be determined by the magnitude of PN junction leakage current that occurs during application of a reverse voltage of a set withstand voltage.

After forming the n-type semiconductor regions 4 in this way, the implanted impurity is subjected to activation-annealing, which is normally performed; the ohmic electrode 6 is formed over the back surface of the n⁺ SiC substrate; and the Schottky electrode 5 is formed over the surface of the n⁻ drift layer 2 and patterned into the desired size. Thus, the semiconductor device according to the present invention shown in FIG. 9 is completed.

While only the main portions of the diode have been described thus far, an electric field concentration relaxing structure, which is typically formed around the chip, is formed by normal lithography and dry etching, and ion implantation before, during, or after the manufacturing process steps shown in FIGS. 11 and 12.

While the p-type semiconductor regions 3 and then the n-type semiconductor regions 4 are formed in the third embodiment, these regions may be formed in reverse order. In this case, the n-type semiconductor regions 4 are formed; subsequently, the mask material 7 is additionally deposited; and etch-back is performed by normal dry etching. Thus, a mask material 7 for forming the p-type semiconductor regions 3 having a smaller width than the n-type semiconductor regions 4 is formed.

While the n-type semiconductor regions 4 are formed with a width greater than the p-type semiconductor regions 3 in the third embodiment, they may be formed using the same mask pattern. Thus, the step of reshaping the mask material 7 can be omitted, simplifying the process. A sectional structure is illustrated in FIG. 10.

While, in the third embodiment, the electrodes are formed over the back and front surfaces immediately after activation-annealing the implanted impurity, an oxidation process and a sacrificial oxidation step of eliminating a damaged layer which has entered a surface of the n⁻ drift layer 2 may be performed after activation-annealing the implanted impurity.

While, in the third embodiment, the electrodes are formed over the back and front surfaces immediately after activation-annealing the implanted impurity, a surface protection film may be formed of SiO₂ or the like over the surface of the n⁻ drift layer 2 by CVD to protect the surface of the n⁻ drift layer 2. In this case, an aperture is formed only in the region in which a Schottky electrode is to be formed, of the formed surface protection film. Alternatively, a surface protection film may be formed after performing the sacrificial oxidation step.

### Fourth Embodiment

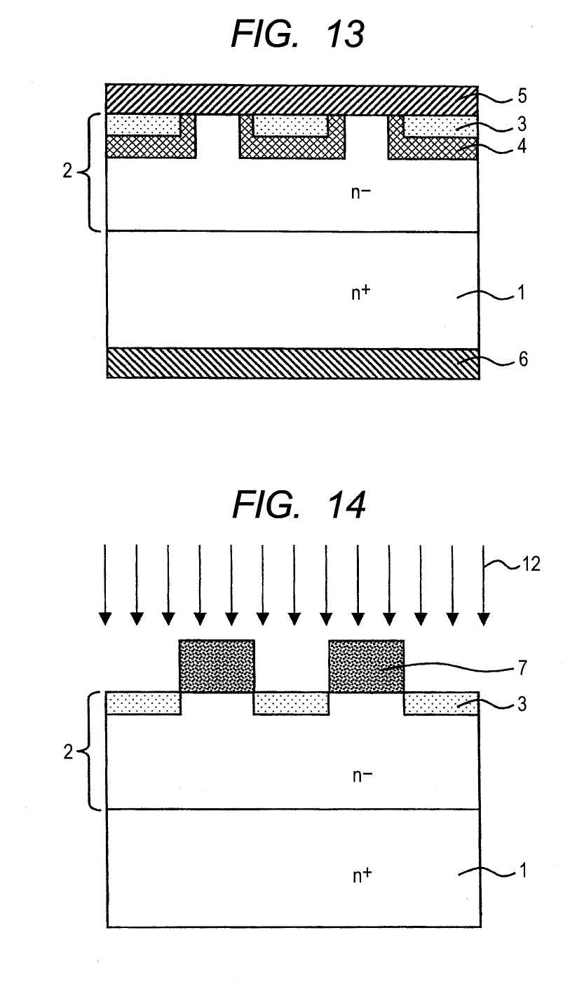

FIG. 13 is a diagram showing a sectional structure of a semiconductor device according to a fourth embodiment of the present invention. FIG. 13 differs from FIG. 9 shown in the third embodiment in that the n-type semiconductor regions 4 are also formed on side surfaces of the p-type semiconductor regions 3 so as to extend to the surface of the n⁻ drift layer 2 and make Schottky-coupling. Adjacent n-type semiconductor regions 4 are disposed at predetermined intervals. Effects of the third embodiment are substantially similar to those shown in the first embodiment to one degree or another.

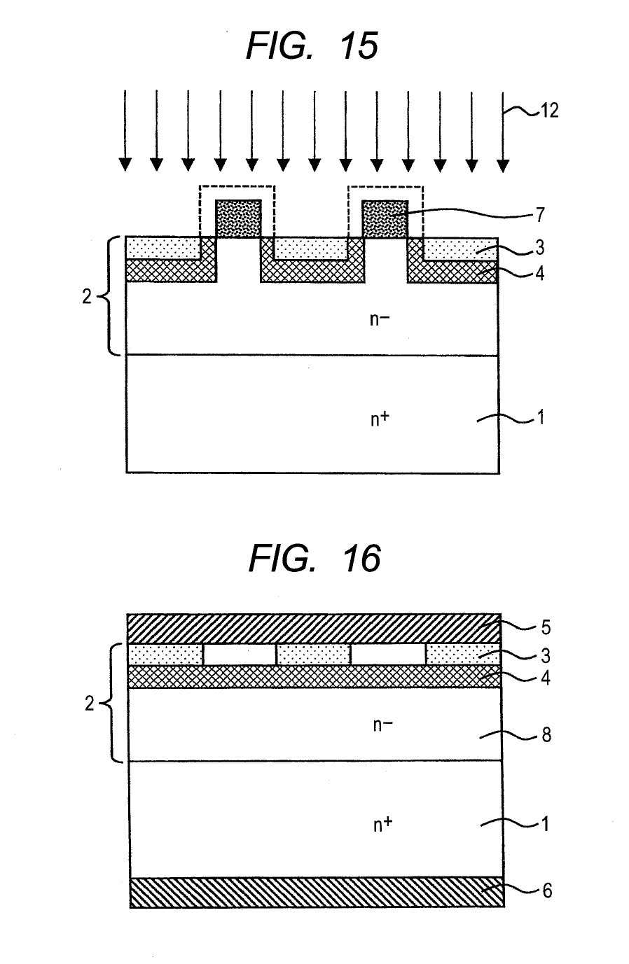

FIGS. 14 and 15 are diagrams each showing a sectional structure in an example manufacturing process step according to the fourth embodiment.

The fourth embodiment differs from the third embodiment in an ion implantation condition for forming the n-type semiconductor regions 4 of FIG. 15. By performing multi-stage implantation with low acceleration energy, the n-type semiconductor regions 4 are formed so as to extend to the surface of the n⁻ drift layer 2.

Other methods according to the fourth embodiment include a method of forming the n⁻ drift layer 2 into a trench shape by normal dry etching, then epitaxially growing a SiC layer to serve as the n-type semiconductor regions 4 and a SiC layer to serve as the p-type semiconductor regions 3, and performing planarization polishing by chemical mechanical polishing (CMP) until reaching the surface of the n⁻ drift layer 2. In this case, the n-type semiconductor regions 4 and the p-type semiconductor regions 3 can be formed without using ion implantation. Accordingly, the impurity concentrations or widths thereof can be correctly controlled.

### Fifth Embodiment

FIG. 16 is a diagram showing a sectional structure of a semiconductor device according to a fifth embodiment of the present invention. FIG. 16 differs from FIG. 9 shown in the third embodiment in that the n-type semiconductor region 4 is formed as a single layer without being divided. That is, the n-type semiconductor region 4 is also disposed between the p-type semiconductor regions 3 and between the Schottky electrode 5 and the SiC substrate 1. Further, the n-type semiconductor region 4 is disposed as separated from the Schottky electrode 5 by a predetermined distance. Effects of the fifth embodiment are substantially similar to those shown in the first embodiment to one degree or another.

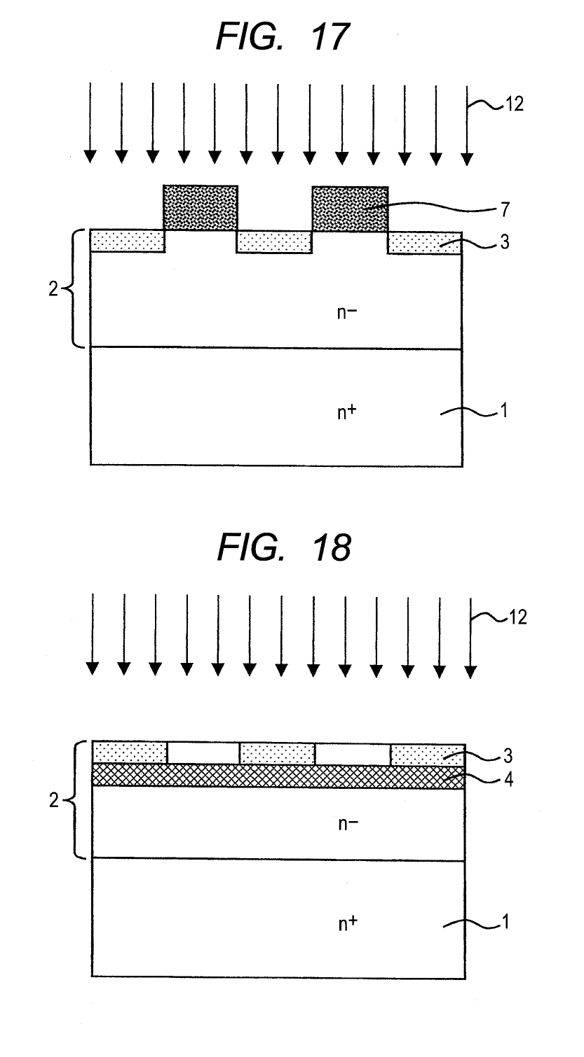

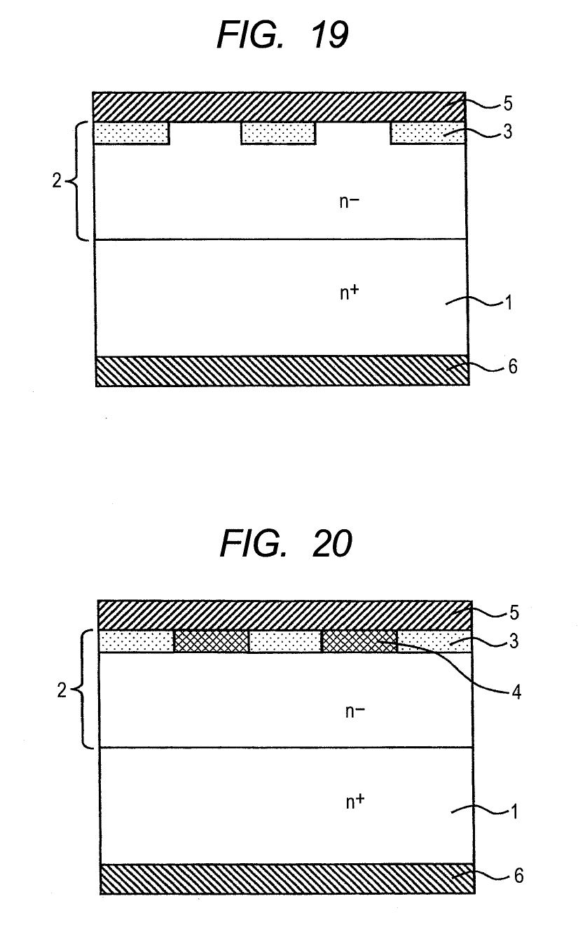

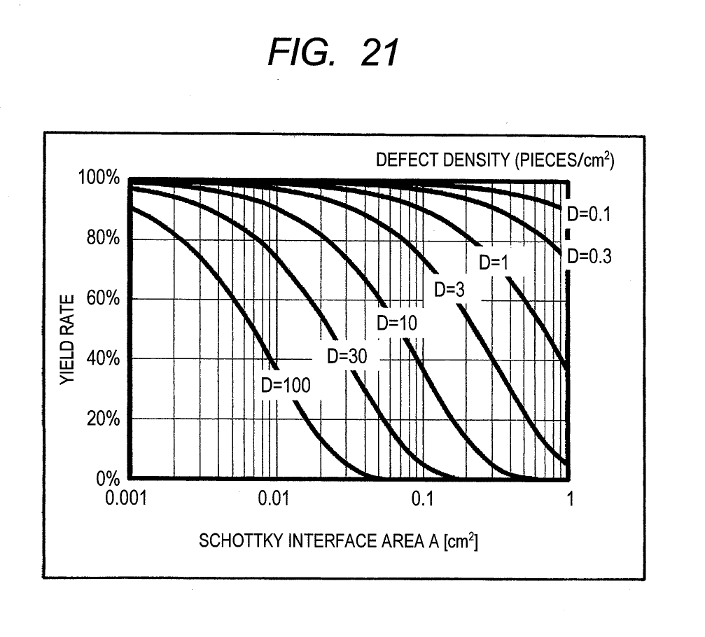

FIGS. 17 and 18 are diagrams each showing a sectional structure in an example manufacturing process step according to the fifth embodiment.

The fifth embodiment differs from the third embodiment in the region into which ions are to be implanted when forming the n-type semiconductor region 4 of FIG. 18. In the fifth embodiment, the n-type semiconductor region 4 is formed by ion-implanting an n-type impurity into the entire surface of the region in which a JBS structure is to be formed.

Other methods according to the fifth embodiment include a method of epitaxially growing an n⁻ SiC layer having the same impurity concentration as the n-type semiconductor region 4 and the n⁻ drift layer 2 over a surface of the n⁻ drift layer 2 and then forming the p-type semiconductor regions 3 by ion implantation. In this case, the n-type semiconductor region 4 can be formed in such a manner that the impurity concentration and thickness thereof are well controlled.

The present invention has been described using the first to fifth embodiments. While the second embodiment has been described using the first embodiment, the second embodiment is also applicable to the third to fifth embodiments. In this case, the n-type semiconductor region 4 disposed between the p-type semiconductor regions 3 and the guard ring 9 of FIG. 8 is replaced with the n-type semiconductor regions 4 according to the third to fifth embodiments.

### LIST OF REFERENCE SIGNS

1 n⁺ SiC substrate
2 n⁻ SiC drift layer
3 p-type semiconductor region
4 n-type semiconductor region
5 Schottky electrode
6 ohmic electrode
7 mask material
8 n⁻ SiC layer
9 guard ring
10 insulating film
11 aperture
12 ion

1-15. (canceled)

16. A semiconductor device comprising:
a silicon carbide substrate of a first conductivity-type;
a first semiconductor layer of the first conductivity-type formed over the silicon carbide substrate and having a first impurity concentration;
a second semiconductor layer of the first conductivity-type formed over the first semiconductor layer and having a second impurity concentration higher than the first impurity concentration;
a plurality of first semiconductor regions of a second conductivity-type formed over a surface in the second semiconductor layer at predetermined intervals, the second conductivity-type being opposite to the first conductivity-type;
a second semiconductor region of the second conductivity-type formed in the second semiconductor layer so as to surround the first semiconductor regions when seen from above;
a Schottky electrode which is Schottky connected to the second semiconductor layer; and
an ohmic electrode which is ohmic connected to a back surface of the silicon carbide substrate,
wherein the first semiconductor regions have first and second patterns, the first pattern being disposed below the Schottky electrode with a spacing between the Schottky electrode and the first pattern, the second pattern having a terminal of the Schottky electrode disposed thereover, and
wherein the second semiconductor region is disposed with a depth greater than respective depths of the first and second patterns.

17. The semiconductor device according to claim 16,
wherein the first pattern is a stripe pattern.

18. The semiconductor device according to claim 17,
wherein the second pattern is a ring pattern having the terminal of the Schottky electrode disposed thereover.

19. The semiconductor device according to claim 18,
wherein the ring pattern is a guard ring.

20. The semiconductor device according to claim 18,
wherein an insulating film is disposed between the ring pattern and the Schottky electrode.

21. The semiconductor device according to claim 20,
wherein the terminal of the Schottky electrode is disposed over the insulating film.

22. The semiconductor device according to claim 18,
wherein the strip pattern and the ring pattern are formed in the same step.

23. The semiconductor device according to claim 18,
wherein the stripe pattern has a depth different from a depth of the ring pattern.
